(19) United States
(12) Patent Application Publication
(10) Pub. No.: US 2009/0045164 A1
(43) Pub. Date: Feb. 19, 2009

(54) "UNIVERSAL" BARRIER CMP SLURRY FOR USE WITH LOW DIELECTRIC CONSTANT INTERLAYER DIELECTRICS

(75) Inventors: Janos Farkas, Saint Ismier (FR); Philippe Monnoyer, Grenoble (FR); Brad Smith, Gieres (FR); Mark Zaleski, Grenoble (FR)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freescale Semiconductor, Inc., Austin, TX (US)

(21) Appl. No.: 12/162,173

(22) PCT Filed: Feb. 3, 2006
(86) PCT No.: PCT/EP2006/002851

§ 371 Date: Jul. 25, 2008

(51) Int. Cl. H01L 21/306; C09G 1/02; H01L 21/304

(52) U.S. Cl. 216/38; 156/345.13; 252/79.1

(57) ABSTRACT

During processing of a semiconductor wafer bearing a structure including a low-k dielectric layer, a cap layer and the metal-diffusion barrier layer, a chemical mechanical polishing method applied to remove the metal-diffusion barrier material involves two phases. In the second phase of the barrier-CMP method, when the polishing interface is close to the low-k dielectric material, the polishing conditions are changed so as to be highly selective, producing a negligible removal rate of the low-k dielectric material. The polishing conditions can be changed in a number of ways including: changing parameters of the composition of the barrier slurry composition, and mixing an additive into the barrier slurry.

The present invention relates to the field of integrated circuit (IC) manufacture and, more particularly, to chemical mechanical planarization or polishing (CMP) of wafers bearing metallic contacts and interconnects and low or ultra-low dielectric constant (LK or ULK) interlayer dielectrics.

It is to be understood that in the present document (unless the context requires otherwise) references to low dielectric constant” (or “low-k”) materials denote materials having a dielectric constant lower than about 3.0. Thus, these references encompass structures etched in so-called “ultra-low-k” (ULK) materials (having k≦2.5). Moreover, references to “semiconductor wafers” are intended to include wafers made of different materials, e.g. silicon, germanium, gallium arsenide, silicon-on-insulator, etc., that are used in the manufacture of semiconductor devices.

As scaling of ICs has proceeded to ever smaller dimensions, it has been proposed to replace the traditional aluminium interconnects by copper interconnects, and to replace the conventional dielectric material, SiO₂, by materials having lower dielectric constant (k). Generally, a protective cap layer is provided over the low-k dielectric material in view of the mechanical weakness of such materials and so as to improve adhesion properties.

It is difficult to apply conventional manufacturing techniques to wafers bearing copper/low-K structures. More particularly, when conventional CMP processes are applied to planarize a Cu interconnect layer associated with a low-k dielectric layer there will typically be problems such as delamination or mechanical or compositional damage of the low-k dielectric layer.

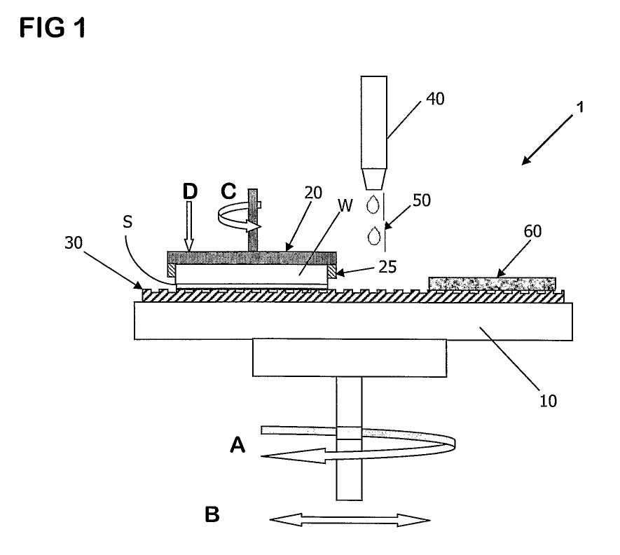

A typical rotary apparatus for performing a CMP process is illustrated schematically in FIG. 1.

The CMP apparatus of FIG. 1 includes a platen 10, as well as a head 20 adapted to hold a semiconductor wafer W, for example by means of a retaining ring 25. A removable polishing pad 30 is provided on the platen 10; this polishing pad may be changed, as required, during the polishing process. The surface of the polishing pad is relatively rough which leads to partial, rather than continuous, contact between the polishing pad and the surface S of the wafer (the surface roughness is exaggerated in FIG. 1). A delivery system 40 supplies slurry 50 to the interface between the polishing pad 30 and the surface S of the wafer W. A pad-conditioner 60 serves to revive the surface of the polishing pad 30. An exhaust and drain (not shown) remove unwanted materials from the polishing system.

The platen 10 is driven in rotation (as indicated by arrow A in FIG. 1) and/or is driven with a reciprocating motion—in the case of orbital motions—(as indicated by arrow B). The head 20 bearing the wafer W is also driven in rotation (as indicated by arrow C in FIG. 1) and has its axial position controlled so as to regulate a down force (indicated by arrow D) that presses the wafer against the polishing pad. Because of the relative motion between the wafer W and the polishing pad 30, and the slurry supplied at the interface between them, the surface S of the wafer is polished.

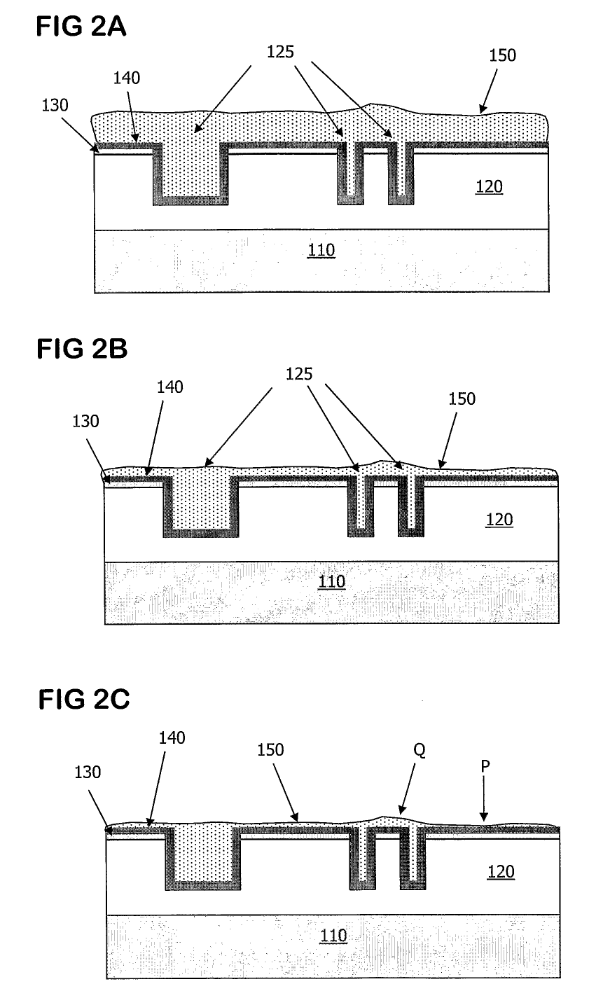

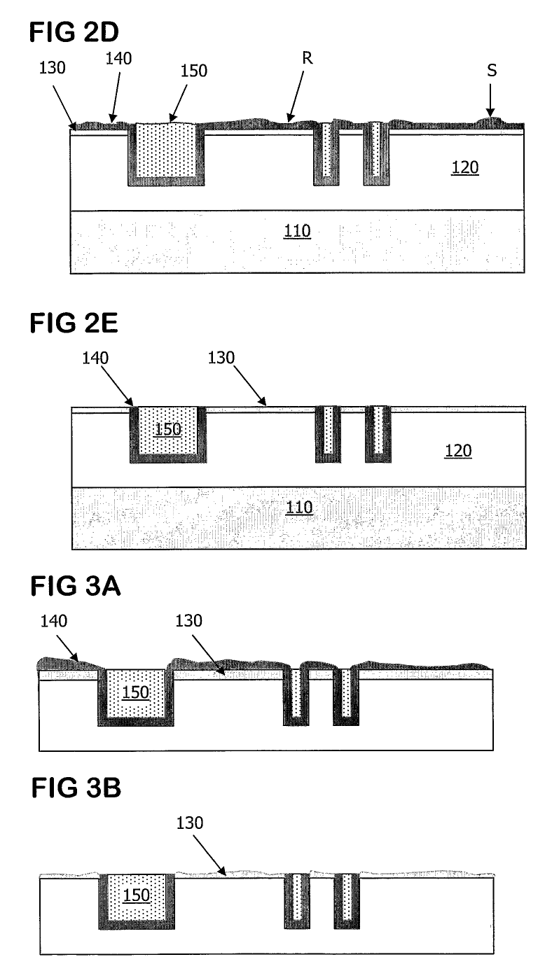

A CMP process applied to a wafer using low-k dielectric material typically includes a number of different stages, as shall now be explained with reference to FIG. 2. FIG. 2 shows a greatly simplified structure to aid understanding. The skilled person will readily understand that the comments which follow apply in general to polishing of various etched structures (including single damascene and dual damscene structures, to name but two).

As illustrated in FIG. 2A, at the start of the CMP process there will generally be a conductive layer 110 covered by a passivation layer (not shown) made of silicon carbide, silicon carbon nitride, etc. with an interlayer dielectric layer 120 on top made of a low-k material and having structures 125 such as trenches and vias etched therein, a cap layer 130 formed over portions of the dielectric layer 120 outside the trenches and vias, a copper-diffusion barrier layer 140 formed over the cap layer 130 and formed over the sidewalls of the trenches and vias 125, and a copper layer 150 deposited over the diffusion barrier layer 140. The copper is intended to fill the structures 125 etched in the dielectric. The major purpose of the CMP process is to remove portions of the copper layer 150 and barrier layer 140 that are outside the structures 125.

In an initial phase of the CMP process, bulk copper is removed at a rapid rate using a particular combination of slurry and operating conditions (e.g. the down force applied to the wafer, rotational velocity of the platen, rotational velocity of the wafer carrier, slurry flow rate, etc.). The point at which the underlying diffusion barrier layer becomes exposed (e.g. as at location P in FIG. 2C) is referred to as the “clearing” of the copper. Often this first, bulk-copper-removal phase of the CMP process is modified about 2000 Å before clearing of the copper—that is, while there is still a copper layer about 2000 Å thick above the top of the trenches and vias—as illustrated in FIG. 2B (although FIG. 2B shows only trenches, not vias, in order to simplify the drawing). The modification generally involves alteration of the operating conditions—e.g. reduction of the down force—so as to reduce the rate of copper removal, to increase the selectivity of the polishing process with regard to the barrier material, and thereby to enable copper clearing to be detected more precisely. Polishing continues under the modified conditions.

During this second stage, although copper becomes entirely removed at certain locations (e.g. location P in FIG. 2C) over the surface of the wafer, there will be other locations (e.g. location Q) where undesired copper is still present. This is typically above narrow trenches, since the copper layer 150 is typically thickest there due to the copper plating process. Accordingly, further polishing of the copper is required. This further polishing is often designated “overpolishing” because at some locations it results in more polishing of the copper than is necessary to clear. The overpolishing process is designed to continue until all undesired copper has been removed (or until copper has been removed to a desired extent, followed by a timed polish to finish).

During the copper overpolishing stage, it is possible for some of the diffusion barrier material to be thinned at certain regions on the wafer surface, i.e. regions where the initial copper layer had been relatively thinner, as illustrated in FIG. 2D (see the regions labelled R). However, after the clearing of the copper, diffusion barrier material will still be present over the wafer surface (e.g. see the location labelled S in FIG. 2D) because of local variations in the thickness of the initial-formed barrier layer 140 (these variations are exaggerated in FIG. 2D, for the purposes of illustration).

In some cases, barrier material begins to clear during the copper polish, stopping on the underlying cap layer. However, even in this case it is likely that some residual barrier material will remain on portions of the cap layer, which would cause leakage if it were not removed.

Thus, after the copper clearing it is still necessary to remove the barrier layer material remaining on the surface of the wafer. This next stage of polishing is often referred to as “barrier-CMP” (whereas the preceding stages are referred to as “copper-CMP”). The barrier-CMP stage generally involves use of a different slurry from that used in the earlier, Cu-CMP stages. Usually the barrier-CMP stage continues until the diffusion barrier has been completely removed (barrier clearing), and typically some overpolishing will be performed so as to counteract non-uniformities in the barrier layer thickness and variation in the removal rate.

When the dielectric layer 120 is made of a conventional dielectric material (i.e. not a low-k material) there is often no cap layer 130 and it is common to continue barrier polishing so as to remove a thin portion at the top of the dielectric layer (so as to correct for patterning problems and remove dielectric faceting).

When the dielectric layer 120 is made of a low-k material and is topped with a cap layer 130, there are two different approaches that are used for determining when to end the overall CMP process:
a) the polishing stops while there is still a thin layer of cap material protecting the underlying dielectric (as illustrated in FIG. 2E), resulting in a disadvantageous increase in dielectric constant, or
b) polishing is continued until all of the cap layer 130 is removed (even if some of the underlying dielectric material is also removed), so as to ensure that a desired low dielectric constant is achieved, but there may be damage to the low-k dielectric material.

Often the defectivity on the wafer is acceptable after barrier-polishing is complete. However, sometimes an additional buff step, or a final rinse, may be performed in order to reduce defectivity still further.

The slurries that are generally used in CMP processes comprise abrasive particles in suspension: these abrasive particles often consist of silicon oxide (silica—in fumed or colloidal form), aluminium oxide (alumina), cerium oxide (ceria), polymer or coated polymer. In addition to the abrasive particles, conventional slurries generally contain several of the following components: water; oxidisers, such as hydrogen peroxide, hydroxylamine or potassium iodate; corrosion inhibitors, such as benzotriazole, triazole, imidazole, etc; and pH adjusters, such as potassium or more preferably ammonium hydroxide; and they may include other additives such as surfactants (dispersants); accelerators; chelating compounds; biocidal agents and lubricating agents.

Most slurries remove material from the wafer surface by a combination of chemical action and mechanical action (notably abrasion by the abrasive particles in the slurry). The composition of the slurry is usually controlled so as to obtain a desired selectivity of the polishing process—for example, in the “copper clearing” stage of the CMP process the slurry used might be an acidic solution whose pH is set, within the range of 2.0 to 7.0, at a value appropriate to produce a desired removal rate of copper relative to the underlying barrier layer. Moreover, other environmental conditions (such as temperature, pressure, velocity, etc.) operative during the CMP process are also set to desired values.

The diffusion barrier layer will generally be formed of Ta or TaN when copper interconnects are used. The low-k material may be substantially any low-k material, for example: later versions of Black Diamond™ (namely Black Diamond IIX and III™, porous low-k SiCOH) made by Applied Materials Inc. of California, USA, Orion™ made by Trikon Technologies Inc of Newport, UK, p-SiLK™ (the porous version of SILK) made by The Dow Chemical Company, Zirkon LK™ (porous methyl silsesquioxane) made by Rohm and Haas of Philadelphia, USA, LKD-5109 made by JSR Corp of Japan and Aurora 2.7™ and Aurora ULK™ (carbon-doped silicon oxide) made by ASM International NV of Bilthoven, Netherlands. The cap layer will be formed of a different material depending upon the nature of the underlying low-k dielectric but, in some cases, it may be a layer of SiO₂.

Efforts are underway to develop an overall CMP process that will be compatible with Cu interconnects and low-k dielectric materials. These efforts involve optimization of the CMP tool (apparatus) and/or the consumables involved in the CMP process (notably slurries, polishing pads and pad conditioners).

One of the complications that arises when attempting to optimize the CMP process applied to copper interconnect/low-k dielectric structures is the fact that the optimum slurry for use in the barrier-CMP stage of the overall CMP process will vary depending upon the particular combination of barrier material, low-k material and cap layer combination that is involved. This can be better understood when it is realized that the barrier-polishing slurry will need a selectivity that depends on four materials: i.e. it may be desired to use a so-called “non-selective” slurry which produces the same removal rates for the metal layer 150, barrier layer 140, cap layer 130 and low-k dielectric 120 (i.e. a ratio of removal rates of metal:barrier:cap:low-k dielectric close to 1:1:1:1), or perhaps to use a barrier-polishing slurry that is highly selective to the capping layer (e.g. having a ratio of removal rates 1:>>1:1:1). Thus, if a particular manufacturer were to be interested in fabricating integrated circuits using wafers bearing different combinations of low-k dielectric materials and cap layers he would be obliged to stock as many different barrier slurries as there are different combinations of cap layer material and low-k dielectric and, possibly also, metals and barrier layers.

Finding an appropriate formulation for a barrier slurry is particularly difficult in view of the fact that often the cap layer material will be chemically fairly similar to the underlying low-k dielectric, but the low-k dielectric will typically be much more delicate; for example, a SiO₂ cap layer may be used on a low-k dielectric material which is a carbonated silicon oxide material.

In general, the polishing rate and selectivity obtainable when using a given slurry will vary depending upon the composition of the slurry. Certain commercially-available slurries are said to be “tuneable”, meaning that the precise polishing rate and selectivity obtainable using such a slurry can be tailored for the customer, for example, by varying the concentration of a component in the slurry. However, even in such cases the slurry composition will not be changed after implementation.

Hitherto, known barrier-polishing methods use a single barrier slurry whose composition remains constant throughout the barrier-polishing process, and constant polishing conditions throughout the barrier-polishing process.

In certain, particular contexts there have been proposals for varying the composition of a copper-CMP slurry while a particular stage in the copper polishing process is in progress. For example, U.S. Pat. No. 6,589,099 suggests altering the oxidizer concentration of a slurry during a Cu-CMP process, and U.S. Pat. No. 5,985,748 suggests changing the abrasive content, in both cases so as to decrease the copper removal rate in order to facilitate determination of the endpoint of copper CMP. US 2004/037740 proposes adding an organic surfactant to a Cu-CMP slurry during the copper over-polishing stage in order to reduce the wetting of an underlying low-k dielectric layer by the slurry. No cap layer is mentioned in US 2004/037740.

Certain other proposals exist suggesting that polishing rate and/or selectivity can be adjusted during a Cu-CMP process by varying hardware conditions such as the pressure, velocity or temperature of the polishing pad. However, such methods can lead to an undesirable change in planarity and uniformity, and/or the inability to remove residuals, and/or to a set of conditions that produce a polishing rate that is too slow for practical purposes (i.e. throughput would be too low).

The above-described problems arise not only in the case where the low-k dielectric material is used in association with metal contacts and interconnects that are made of copper but also in the case where contacts/interconnects made of other metals are used, for example tungsten, silver, aluminium, etc. with damascene architecture

It is desirable to develop a barrier-CMP process that is compatible with metal interconnect/low-k dielectric arrangements and, more particularly, which can remove the cap layer with little or no damage to the underlying low-k dielectric material.

The present invention provides a method of barrier chemical mechanical planarization as set forth in the accompanying claims.

The present invention further provides chemical mechanical planarization apparatus as set forth in the accompanying claims.

The present invention yet further provides a barrier-CMP slurry as set forth in the accompanying claims.

Features and advantages of the present invention will become clear from the following description of preferred embodiments thereof, given by way of example, illustrated by the accompanying drawings, in which:

FIG. 1 is a diagram schematically illustrating the main components of a conventional CMP apparatus; and

FIG. 2 is a diagram illustrating a CMP process applied to a structure including copper interconnects and an underlying dielectric structure bearing a cap layer, in which FIGS. 2A to 2E illustrate respective different stages of the CMP process;

FIG. 3 is a diagram illustrating a barrier-CMP process according to the present invention applied to a structure including copper interconnects and an underlying low-k dielectric structure bearing a cap layer, in which FIGS. 3A to 3B illustrate respective different phases of the barrier-CMP process; and

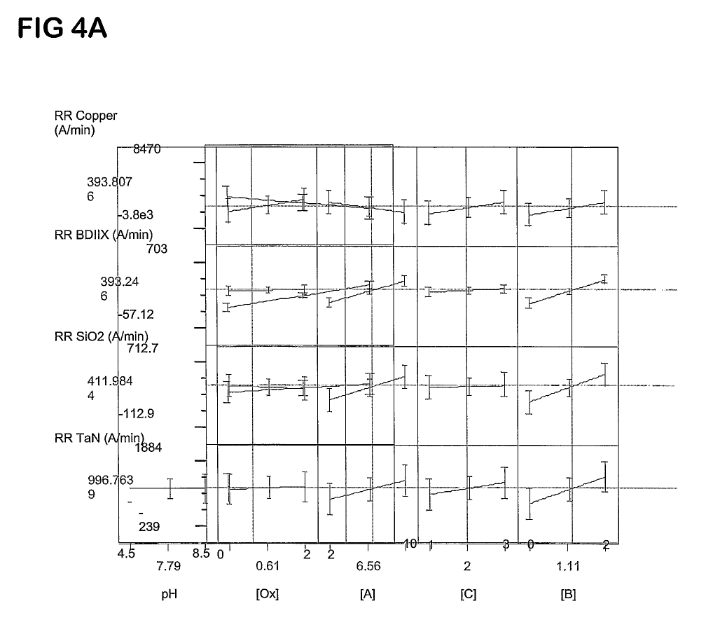

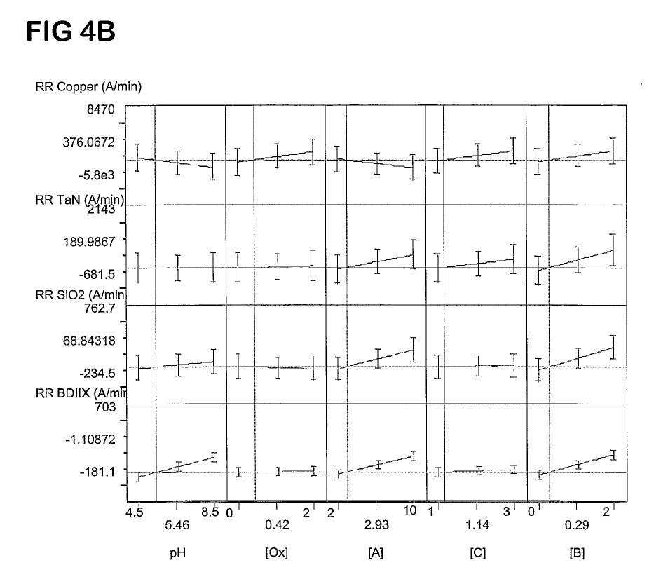

FIG. 4 is a set of graphs, produced during a “design of experiment” process, illustrating how the removal rate of different selected materials varies with barrier slurry composition, in which:

FIG. 4A uses y-axes marked with a first set of scales and illustrates a first barrier slurry composition producing a first combination of removal rates of the selected materials, and

FIG. 4B uses y-axes marked with a second set of scales and illustrates a second barrier slurry composition producing a second combination of removal rates of the selected materials.

It is helpful to consider what happens during chemical mechanical polishing of low-k dielectric materials and their cap layers. Consider the case of a system involving a carbonated silicon dioxide low-k dielectric material (here designated SiOC) topped by a SiO₂ cap layer. It has been found that the ease with which these materials polish depends on the population of hydroxyls at the surface. SiO₂ has a relatively large number of surface hydroxyls and so will polish under milder conditions—in terms of downforce, slurry composition, etc.—than the SiOC low-k material (which has a smaller population of surface hydroxyls). It can be considered that the energy barrier to initiate removal of material from the surface of SiOC is greater than the energy barrier for initiating removal of material from the surface of SiO₂.

Based on this factor, the inventors have developed a new barrier-CMP method in which the slurry and the conditions of the barrier-CMP process are controlled so that when polishing is taking place close to the boundary between the cap layer and the low-k dielectric, the polishing conditions are such that they are too mild to initiate polishing of the low-k dielectric and yet still sufficiently severe to polish the cap layer. However, in the initial stage of barrier polishing, when the surface being polished is relatively far away from the low-k dielectric material, harsher polishing conditions are used. These harsher polishing conditions provide the desired selectivity of the polishing process with adequate planarity in the finished product and adequate throughput (these harsher polishing conditions produce higher removal rates of material and, thus, speed up the overall polishing process).

In other words, the barrier-CMP method of the present invention is designed to apply first polishing conditions (in terms of barrier slurry composition and, optionally, operating conditions) at the start of barrier-CMP, and second polishing conditions later on during the barrier-CMP process, notably, at a time when the polishing is coming close to the boundary between the cap layer and the underlying low-k dielectric.

As illustrated in FIG. 3A, during the initial stage of the new barrier-CMP process the polishing process is relatively far from the underlying low-k dielectric and so it is not critical to consider the effect of the first polishing conditions on the removal rate of the low-k dielectric. This relaxes constraints on the design of the first polishing conditions and, in particular, allows a somewhat wider choice of barrier slurry than would have been the case if the slurry's selectivity towards the low-k dielectric material had needed to take a particular value.

It is preferred that, during the initial stage of the new barrier-CMP process, the first polishing conditions should be such as to be substantially non-selective between the metal and the cap layer (i.e. to produce a ratio of removal rates of [metal:cap layer] that is close to [1:1]), in order not to interfere with the planarity of the surface—assuming that a reasonably planar surface was present at the end of copper clearing (if not, the metal removal rate could be adjusted during the initial stage of barrier CMP in order to make the desired correction in planarity). The removal rate of the barrier material should be at least as high as the removal rates of the metal and of the cap layer material. It is believed to be preferable for the removal rate of barrier material to be greater than the removal rates of metal and of cap layer material during this stage of the polishing process.

As illustrated in FIG. 3B, during the later stage of the new barrier-CMP process, when the polishing interface is close to the low-k dielectric layer 120, the second polishing conditions should be such as to be highly selective with regard to the metal and cap layer relative to the underlying low-k dielectric, that is, they should be such as to produce a ratio of removal rates of [metal:cap layer:low-k dielectric material] that is close to [non-negligible:non-negligible:0]. Once again, it is desirable for the removal rate of the barrier layer material to be at least as great as (preferably greater than) the removal rate of the metal and of the cap layer material.

As shall be discussed below, the desired modulation of polishing conditions can be performed in a number of different ways, including, but not limited to, changing the composition of the barrier slurry in terms of one or more factors such as: pH, oxidiser content, abrasive content, corrosion-inhibitor content, complexing-agent content, etc.

In order to prove the viability of the new method, the inventors considered whether or not it would be possible to produce a barrier slurry composition that could be modulated in order to produce the desired pattern of removal rates in a system involving copper contacts/interconnects, a TaN barrier layer, a SiO₂ cap layer, and a Black Diamond IIX™ low-k dielectric material. The inventors performed a “design of experiment” process which involved modelling the effect that varying the barrier slurry composition would have on the removal rate of the selected materials. FIG. 4 illustrates the results of this design of experiment process.

FIG. 4 illustrates the effect of varying the pH, oxidiser content [Ox], abrasive content [A], corrosion-inhibitor content [C], and complexing agent content [B] of a barrier slurry on the removal rates of copper (top row of traces in FIGS. 4A and 4B), TaN (fourth row of traces in FIG. 4A, second row of traces in FIG. 4B), SiO₂ (third row of traces in FIGS. 4A and 4B) and Black Diamond IIX™ (second row of traces in FIG. 4A, bottom row of traces in FIG. 4B).

The inventors determined that there was a slurry composition (Composition A) which gave ratios of removal rates which would be suitable for the first stage of the new barrier-CMP process. FIG. 4A illustrates the selected barrier slurry composition. More particularly, the following barrier-slurry composition, Composition A:

pH=7.79

majority component=water

oxidiser content=0.61% H₂O₂ by weight

abrasive (silica) content=6.56% by weight

corrosion inhibitor=2% 1,2,4 triazole by weight

complexing agent content=1.11% citric acid by weight

gave the following combination of removal rates:

copper removal rate=393.8 Å per minute

TaN removal rate=996.8 Å per minute

SiO₂ removal rate=412 Å per minute

Black Diamond IIX™ removal rate=393.2 Å per minute,

which gives an actual Cu:SiO₂ ratio of 0.96:1 which is substantially equal to the preferred ratio of 1:1.

Moreover, the inventors found that modifying the slurry composition to a Composition B (as illustrated in FIG. 4B):

pH=5.46

majority component=water

oxidiser content=0.42% H₂O₂ by weight

abrasive content=2.93% by weight

corrosion inhibitor=1.14% 1,2,4 triazole by weight

complexing agent content=0.29% citric acid by weight

produced a pattern of removal rates:

copper removal rate=376.1 Å per minute

TaN removal rate=190 Å per minute

SiO₂ removal rate=68.8 Å per minute

Black Diamond IIX™ removal rate≈0 Å per minute,

that is substantially equal to that desired for the second stage of the new barrier-CMP process.

By modulating the barrier slurry composition when the polishing interface approaches the underlying low-k dielectric material, the method of the present invention makes it possible to stop polishing on the low-k dielectric layer (that is, to stop polishing when the boundary between the cap layer and the low-k dielectric is reached), even when ultra-low dielectric constant (ULK) materials are used.

### FIRST PREFERRED EMBODIMENT

In the first preferred embodiment of barrier-CMP method according to the present invention, the polishing conditions are changed during the barrier-CMP process by modifying the composition of the barrier slurry.

For instance, taking the example considered in the above-described design of experiment process, when applying the first preferred embodiment of the new barrier-CMP method to a system involving copper contacts/interconnects, a TaN barrier layer, a SiO₂ cap layer and a Black Diamond IIX™ low-k dielectric, the barrier CMP process could begin with a first phase involving use of a barrier slurry having Composition A above, resulting in substantially equal polishing rates of the copper and the cap layer, and a somewhat higher removal rate of the barrier layer.

At a particular point when it is considered that the polishing interface is approaching the boundary between the cap layer and the low-k dielectric, this barrier slurry composition could be changed to Composition B above, resulting in continued polishing of the copper, barrier and cap layer, but substantially no polishing of the underlying low-k dielectric even when the cap layer clears. Accordingly, the new barrier CMP process can achieve polishing in this system substantially reducing damage to the low-k dielectric.

Moreover, the polishing process is efficient and rapid, and there are fewer constraints on the barrier slurry composition, at least for the first phase of the new process, than would be the case if the selectivity of the barrier slurry towards the low-k dielectric material had needed to be taken into account throughout the barrier polish. In particular, the barrier slurry composition for the first phase of the barrier polish can be optimized with respect to the underlying cap layer material, substantially without reference to the nature of the low-k dielectric underneath the cap layer.

According to the barrier-CMP method of the present invention, the polishing conditions should be changed at a time when the polishing interface is close to the underlying low-k dielectric material. Advantageously, this change is implemented when polishing of the cap layer material has already begun but relatively early into polishing of the cap layer (so that the change in selectivity will take effect before the underlying low-k dielectric material has been exposed).

As a practical matter the change will generally be implemented after the “endpoint”, i.e. after the majority of the barrier material has cleared. Typically, cap layers are around 50-100 nm (500-1000 Angstroms) thick and so it would be preferable to implement the change in polishing conditions when the remaining thickness of cap layer material over the dielectric layer is greater than about 20-30 nm.

A number of different techniques may be chosen for controlling the switchover of polishing conditions from the first polishing conditions to the second polishing conditions. More particularly, the change may be implemented at a fixed time after the start of barrier-CMP. Another alternative is to determine the appropriate time point for the change by using a measurement system to dynamically set the change point depending upon that measurement system's evaluation of how polishing is progressing. The measurement system may choose an instant that is related to the endpoint of barrier CMP (as determined by in-situ measurements of properties, such as layer thickness, during the barrier polish of the current wafer), or it may be an automatic process control (APC) system that takes measurements on a succession of wafers and varies the time point for polishing-condition change on a run-to-run (or wafer-to-wafer or lot-to-lot) basis, dependent on measurements made for one or more preceding wafers.

Still further, the unit controlling the implementation of the change in polishing conditions may be arranged to modify the timing of the changeover dependent on historical data relating to repeatable factors, such as a drift in the removal rate as the polishing pad wears. For example, if the removal rate of material by the polishing pad drops by x % per wafer polished, the control unit could delay the changeover of polishing conditions by an extra kx seconds per wafer until the polishing pad is replaced.

If desired, the change in selectivity can be enhanced by altering the operating conditions (wafer rotational velocity, wafer speed across the platen, down force, platen rotational velocity, temperature at the wafer surface, slurry flow rate, etc.) as well as by making a change in the barrier slurry composition.

Although, in the example discussed above, the second polishing conditions differed from the first polishing conditions insofar as five parameters of the barrier slurry had all changed (pH, oxidiser-content, abrasive-content, corrosion-inhibitor-content, and complexing-agent-content), the present embodiment is not limited to this type of change in the polishing conditions. In particular, it is not considered necessary for all five of these parameters of the barrier slurry to be altered when changing from the first polishing conditions to the second polishing conditions. Depending on the particular combination of metal, barrier layer material, cap layer material and low-k dielectric in the structure to be polished, it may well be possible to achieve the desired pattern of selectivities in each phase of the new barrier-polishing process by varying a subset of these parameters (including the case where the variation affects just a single parameter, e.g. just the solids content of the barrier slurry), or by varying other parameters of the barrier slurry—for example by mixing in an additive for the second phase of the new barrier-polishing method.

Indeed, it is believed that, in many cases, it will be possible to find a barrier slurry that is quasi-universal for a given cap layer material. In particular, it is believed to be possible to create a quasi-universal two-component barrier slurry for use in a set of CMP processes which remove barrier layers in structures involving metal (notably copper) interconnects and respective different combinations of low-k dielectric materials with a given cap layer material.

### SECOND PREFERRED EMBODIMENT

More particularly, in a second preferred embodiment of the present invention a barrier-CMP slurry that has a first component is applied during an initial stage of barrier-CMP, and a second component (an additive) is added to the first component as the barrier-CMP process progresses. For a given cap layer material, the same first component can be used in the barrier-CMP slurry. However, the second component may be different depending upon the nature of the low-k dielectric material that underlies the cap layer. Because the second component of the barrier slurry is mixed with the first component only part way through the barrier-CMP process itself, it does not affect the shelf life of the first component.

This approach enables a manufacturer to cater for polishing of wafers having different low-k dielectric materials using a small number of slurries, plus a few additives, rather than having to stock a different slurry for each combination of materials (barrier/cap/low-k dielectric material). It is much simpler and cost-effective for the manufacturer to handle additives rather than additional slurries, especially as the majority of additives will not themselves contain abrasive particles.

This point is especially significant given that the processing of a single semiconductor wafer can often involve multiple polishing steps affecting different types of dielectric materials—e.g. polishing first to fourth metal layers (i.e. M1-4) overlying an ultra-low-k dielectric with a TEOS (tetra-ethyl-orthosilicate or tetra-ethoxy-silane) cap, polishing M5-7 overlying a low-k dielectric with a TEOS cap, and polishing M8-9 overlying standard oxide dielectric. By adopting the approach according to the second embodiment of the invention, the manufacturer can avoid the need to stock extra slurries and/or avoid the need to use dedicated equipment, only needing to stock one or two barrier slurries with a small set of additives.

It is likely that the same cap layer material will be used for several different kinds of low-k and ultra-low-k dielectric materials. Thus, the required “first component” of the barrier slurry will often be the same.

In addition, the present invention should make it possible to change over to the use of ULK dielectric materials whilst still making use of known barrier materials currently used for ordinary low-k dielectric materials (only requiring injection of an appropriate additive into the barrier slurry composition when the polishing interface approaches the ULK material). This reduces costs, and avoids the capital outlay that would otherwise be required when handling additional slurries.

According to the second preferred embodiment of the present invention, the second component of the barrier slurry is a selectivity modifier adapted to change the selectivity of the barrier slurry and, in particular, to alter the removal rate of the cap layer relative to the low-k dielectric material.

A wide variety of different substances may be used as the selectivity modifier, primarily surface functionalizing agents having a polar group and an apolar group. Depending on the polarity of the polar group these substances can be classified as anionic, cationic, zwitterionic or non-ionic. Typical examples of the polar groups in these substances include:
cationic: ammonium and alkylammonium compounds; etc.
anionic: sulfates; sulfonate groups; etc.
non-ionic: amines, notably organic amines (butyl amine diethyl amine, tetramethyl ammonium hydroxide, etc.); amides; acetamides; trifluoroacetamides; ureas; glycols; phenols; etc.
zwitterionic, containing both anionic and cationic groups in the same
molecules: anionic and cationic groups can be similar to above, for example, ammonium, alkylammonium, sulfate and sulfonate groups.

The apolar groups in these substances include: alkyl groups (methyl, ethyl, butyl, isopropyl, etc.) and longer hydrocarbon or fluorocarbon chains; phenyl groups; etc.

According to the second preferred embodiment of the present invention, the second component of the barrier slurry is mixed in with the first component at a desired point in the barrier polishing process.

In the second preferred embodiment of the invention, the timing of introduction of the second component of the barrier slurry is set with a view to implementing a change in the selectivity of the barrier slurry at a time when cap layer material is being removed at least at some points over the wafer surface. Thus, the behaviour of the slurry changes when the polishing interface is close to the low-k dielectric layer.

In other words, when the polishing interface is relatively far from the low-k dielectric layer the composition and behaviour of the barrier slurry according to the second preferred embodiment will be substantially the same for a given barrier layer material and cap layer material, regardless of which low-k dielectric material is underneath. On the other hand, when the polishing interface is close to the low-k dielectric layer, such that the polishing process needs to be attuned to the requirements of that low-k dielectric layer, then according to the second preferred embodiment of the invention the barrier slurry is changed in a manner that is adapted to the particular low-k dielectric material that is in the structure being polished.

The instant at which the second component should be added is substantially the same as the timing of the change in polishing conditions discussed above in relation to the first preferred embodiment of the invention, and can be achieved using the same kind of techniques as discussed above for the first preferred embodiment, namely, by measuring a particular time interval after the start of barrier-CMP, by process control (e.g. APC) based on some parameter measured in relation to the current wafer or in relation to one or more preceding wafers.

The appropriate second component to use in a given case will depend on the low-k dielectric material underlying the cap layer; however, there may be several different substances which can be used as the appropriate “second component” for a given low-k dielectric material. It is particularly preferred that the selectivity modifier should be a substance that modifies the surface hydroxyl groups of the low-k dielectric layer and/or of the slurry particles in view of the fact that these are generally the reactive sites that will be involved in the polishing process.

When using low-k dielectric materials that are chemically similar, and are capped by the same cap layer material, it should be possible not only to make use of the same first component for the first phase of barrier CMP but also to make use of the same second component for the second phase of barrier CMP, just the amount or concentration of the added second component being different for the different low-k materials. It is even possible that the respective second components of the barrier slurry used for certain pairs of different low-k dielectric materials might be precisely the same as each other (in composition, amount and concentration).

The second preferred embodiment of the invention will be better understood from consideration of the following examples.

### FIRST EXAMPLE

First, consider the case where a barrier-CMP process is performed substantially as described above with reference to FIG. 3 on a structure in which layer 120 is the ULK material Black Diamond IIX™, and cap layer 130 is standard undoped SiO₂. According to the second preferred embodiment of the invention, one example of a suitable first component, FC_{eg1}, of the barrier slurry would be a slurry having the composition:

deionized water: 95.7% by weight

hydrogen peroxide: 0.15% by weight

PL2 colloidal silica abrasive from FUSO™: 3.5% by weight

1,2,4-triazole: 0.5% by weight

dibasic ammonium citrate: 0.15% by weight

(pH-adjusted to 4.5 using ammonia)

When using this first component slurry composition the inventors measured the following pattern of removal rates:

copper removal rate=1032 Å per minute

TaN removal rate=394 Å per minute

SiO₂ removal rate=306 Å per minute

Black Diamond IIX™ removal rate=235 Å per minute

When a second component which is 0.01% by weight of ammonium lauryl sulfate is added to the above-defined first component slurry composition, the corresponding removal rates become:

copper removal rate=1440 Å per minute

TaN removal rate=618 Å per minute

SiO₂ removal rate=338 Å per minute

Black Diamond IIX™ removal rate=121 Å per minute

It will be seen that the removal rate of the ULK dielectric material (here Black Diamond IIX™) is significantly reduced when the second component is added to the first component. Moreover, the removal rate of the overlying cap layer material (here SiO₂) is substantially the same (or even higher). This demonstrates that when a second component that is a surfactant such as ammonium lauryl sulfate is added to the first-component slurry of above-described composition, the polishing removal rate selectivity on the ultralow-k dielectric material vs the silicon oxide is significantly increased (that selectivity being the ratio of the removal rate of silicon oxide on the removal rate of Black Diamond IIX).

### SECOND EXAMPLE

Now, consider the case where a comparable CMP process to that of the first example is performed, but this time using a different second component, notably dioctyl sulfosuccinate (named Aerosol OT or AOT).

The inventors measured that when 0.01% by weight of AOT is added to above-defined first component slurry composition, the corresponding removal rates become:

copper removal rate=1217 Å per minute

TaN removal rate=267 Å per minute

SiO₂ removal rate=279 Å per minute

Black Diamond IIX™ removal rate=47 Å per minute

It will be seen that the removal rate of the ULK dielectric material is even further reduced when the second component that is added to the first component is AOT. Moreover, the removal rate of the overlying cap layer material is only very slightly reduced. This demonstrates that when a second component that is a surfactant such as dioctyl sulfosuccinate (named Aerosol OT or AOT) is added to the first-component slurry of above-described composition, the polishing removal rate selectivity on the ultralow-k dielectric material vs the silicon oxide is significantly increased.

It is expected that there will be formulations that are suitable for use as the first component in a barrier-CMP process (because they give the desired pattern of removal rates of barrier layer material/metal/cap layer material) and which, when mixed with a second component that is simply deionised water, have the desired selectivity with respect to a particular underlying low-k dielectric material.

### VARIANT OF THE SECOND EMBODIMENT

In a variant of the second embodiment of the invention, a two-component barrier slurry is still used but, according to this variant, a mix of the first and second components is used during the initial stage of barrier polishing and then, when the polishing interface approaches the underlying low-k dielectric layer, supply of the second component is halted and polishing continues using the first component on its own.

According to this variant, the first and second components will be chosen such that when they are mixed they produce a barrier slurry that gives 1:1 removal rates of metal and a given cap layer material, but the first component when used alone gives high selectivity with respect to a particular underlying low-k dielectric material.

The method according to this variant is liable to be more difficult to control than the method according to the second embodiment per se.

### CMP Apparatus

An advantage of the present invention is that the preferred embodiments thereof can be implemented by suitable adaptation of existing CMP equipment. For example, conventional rotary CMP equipment of the kind illustrated in FIG. 1, or known linear or orbital CMP apparatus, can be arranged to dispense the different barrier-CMP slurry materials according to the first and second preferred embodiments of the invention at the times required by those embodiments.

The skilled person will readily understand that the desired variation in the composition of the barrier slurry can be achieved in a variety of ways. For example, in various designs of known CMP apparatus the slurry composition supplied to the platen is formed by in situ mixing of components which are fed from respective reservoirs, the flow rate of each component being controlled by, for example, a flow controller. Such apparatus can readily be adapted for use in the above-described embodiments of the new barrier-CMP method of the present invention, with the flow rates of the various components of the barrier slurry and/or additive(s) being changed in-between the first and second stages of the barrier-CMP process.

It is particularly simple to make a change to the chemistry involved in the barrier polishing process in CMP apparatus that incorporates a mixing manifold (such as the Novellus Xceda™). The time constant of the mixing/distribution can be minimized with this type of setup.

Certain preferred embodiments of CMP apparatus adapted to implement the first and second preferred embodiments of the invention include a measurement system, such as an automatic process control (APC) system, (not shown in the figures) programmed to control the timing of change of selectivity of the barrier-CMP slurry. In particular, the measurement system may be arranged to control the change in barrier-polishing conditions so that it occurs when a measured parameter on the wafer surface attains a trigger value, e.g. the average thickness of the cap layer reduces to a particular value. If, as seems likely, current laser-based endpoint detection systems are inadequate for use in the method of the present invention, broad spectrum endpoint detection systems should be suitable.

Although the invention has been described above with reference to preferred embodiments thereof, the skilled person will readily understand that the present invention is not limited by the particularities of the above-described embodiments. More particularly, changes and developments may be made to the above-described preferred embodiments without departing from the scope of the present invention as defined in the accompanying claims.

1. A barrier chemical mechanical polishing method for polishing metal-diffusion barrier material in a structure provided on a semiconductor wafer, the structure including a low-k dielectric layer, a cap layer overlying the dielectric layer, and said metal-diffusion barrier material overlying the cap layer, the method comprising the steps of:
polishing the metal-diffusion barrier material using a barrier slurry; and
when the cap layer is being polished, changing the selectivity of the barrier slurry by mixing an additive into said barrier slurry.

2. A barrier-CMP method according to claim 1, wherein said additive depends on the low-k dielectric material in the low-k dielectric layer of said structure.

3. A barrier-CMP method according to claim 1, wherein said additive is adapted to modify surface hydroxyls of the dielectric layer and/or surface hydroxyls of abrasive particles in the barrier slurry.

4. A barrier-CMP method according to claim 1, wherein the step of changing the selectivity of the barrier slurry consists of mixing deionized water into said barrier slurry.

5. A barrier-CMP method according to claim 1, wherein the selectivity-changing step is controlled to occur at a time selected in the group of: a fixed time after the start of barrier-CMP, a time related to the endpoint of barrier CMP, or a time determined by a measurement system.

6. Chemical mechanical polishing apparatus adapted to polish a structure provided on a semiconductor wafer, the structure including a low-k dielectric layer, a cap layer overlying the dielectric layer and metal-diffusion barrier material overlying the cap layer, the apparatus comprising:
slurry-dispensing means for dispensing a barrier slurry to a polishing interface between a semiconductor wafer and a polishing pad; and
control means for controlling the polishing conditions, the control means being adapted to change the selectivity of the barrier slurry by mixing an additive into said barrier slurry when the cap layer is being polished.

7. CMP apparatus according to claim 6, wherein the control means comprises a measurement module for measuring at least one variable during CMP, wherein the measurement module is adapted for changing the polishing conditions at a time related to the value of said measured variable.

8. A barrier slurry adapted for chemical mechanical polishing of metal-diffusion barrier material in a structure provided on a semiconductor wafer, the structure including a low-k dielectric layer, a cap layer overlying the dielectric layer and metal-diffusion barrier material overlying the cap layer, the barrier slurry comprising:
a first component adapted for application during polishing of the metal-diffusion barrier material, and
a second component adapted for mixing in to the barrier slurry at a time when the cap layer is being polished, wherein said second component depends on the low-k dielectric material in said low-k dielectric layer of said structure on the semiconductor wafer, is adapted to change the selectivity of the barrier slurry, and is adapted to modify surface hydroxyls of the dielectric layer and/or surface hydroxyls of abrasive particles in the barrier slurry.

9. A barrier-CMP method according to claim 2, wherein said additive is adapted to modify surface hydroxyls of the dielectric layer and/or surface hydroxyls of abrasive particles in the barrier slurry.

10. A barrier-CMP method according to claim 2, wherein the selectivity-changing step is controlled to occur at a time selected in the group of: a fixed time after the start of barrier-CMP, a time related to the endpoint of barrier CMP, or a time determined by a measurement system.

11. A barrier-CMP method according to claim 3, wherein the selectivity-changing step is controlled to occur at a time selected in the group of: a fixed time after the start of barrier-CMP, a time related to the endpoint of barrier CMP, or a time determined by a measurement system.

12. A barrier-CMP method according to claim 4, wherein the selectivity-changing step is controlled to occur at a time selected in the group of: a fixed time after the start of barrier-CMP, a time related to the endpoint of barrier CMP, or a time determined by a measurement system.

13. Chemical mechanical polishing apparatus adapted to polish a structure provided on a semiconductor wafer, the structure including a low-k dielectric layer, a cap layer overlying the dielectric layer and metal-diffusion barrier material overlying the cap layer, the apparatus comprising:
slurry-dispensing device to a barrier slurry to a polishing interface between a semiconductor wafer and a polishing pad; and
controller for the polishing conditions, the controller being adapted to change the selectivity of the barrier slurry by mixing an additive into said barrier slurry when the cap layer is being polished.

14. CMP apparatus according to claim 6, wherein the controller comprises a measurement module for measuring at least one variable during CMP, wherein the measurement module is adapted for changing the polishing conditions at a time related to the value of said measured variable.
